(19) United States
(12) Patent Application Publication
(10) Pub. No.: US 2005/0224859 A1
(43) Pub. Date: Oct. 13, 2005

(54) Semiconductor storage device

(75) Inventors: Hiroshi Iwata, Ikoma-gun (JP); Akihide Shibata, Nara-shi (JP)

Correspondence Address: BIRCH STEWART KOLASCH & BIRCH, PO BOX 747, FALLS CHURCH, VA, 22040-0747, US

(73) Assignee: Sharp Kabushiki Kaisha, Osaka-shi (JP)

(21) Appl. No.: 10/505,433

(22) PCT Filed: Mar. 3, 2003
(86) PCT No.: PCT/JP03/02421

§ 371 Date: Aug. 24, 2004

(30) Foreign Application Priority Data
Mar. 4, 2002 (JP) 2002-056694
Feb. 12, 2003 (JP) 2003-033678

(51) Int. Cl. H01L 29/788

(52) U.S. Cl. 257/315; 257/321

(57) ABSTRACT

A semiconductor storage device wherein storage of two bits is implemented in one transistor and that can be further minaturized is provided. Two charge holding portions, one on each sidewall of the gate electrode, are formed so as to be independent of the gate insulating film. Thereby, the memory function carried out by the charge holding portions and the transistor operation function carried out by the gate insulating film are separated. The two charge holding portions, formed on opposite sides of the gate electrode, are separated by the gate electrode and, therefore, interference at the time of rewriting can be effectively suppressed. Accordingly, a semiconductor storage device wherein storage of two bits is implemented in one transistor and that is minaturized is provided.

### TECHNICAL FIELD

The present invention relates to a semiconductor storage device, in particular, to a semiconductor storage device composed of a field effect transistor having a function to convert the change of an electric charge to the amount of electric current.

### BACKGROUND ART

There is a memory according to a prior art developed by Saifun Semi conductors Ltd. as a non-volatile memory wherein one field effect transistor allows the storage of two bits (Kohyo (Japanese Unexamined Publication) No.2001-512290).

This memory is configured of a gate electrode 909 formed above a P type well region 901 via a gate insulating film as well as of first and second N type diffusion layer regions 902 and 903 formed in the surface of P type well region 901. The gate insulating film is a so-called ONO (Oxide Nitride Oxide) film wherein a silicon nitride film 906 is sandwiched between silicon oxide films 904 and 905. Charge holding portions 907 and 908, respectively, are formed in silicon nitride film 906 in the vicinity of the edge portions first and second N type diffusion layer regions 902 and 903.

The quantity of charge in each of these charge holding portions 907 and 908 can be read out as a drain current of the transistor and, thereby, two bits of data can be stored in one transistor.

In the memory, however, a gate insulating film has a three-layered ONO film structure, which is difficult to form as a thin film, and a problem arises wherein miniaturization of elements is difficult. That is to say, it is difficult to scale down the film thickness of the gate insulating film and, therefore, short channel effects are increased and miniaturization of elements cannot be achieved. In addition, as channel length decreases, it becomes difficult to separate the two charge holding portions 907 and 908 in one transistor and, therefore, further miniaturization of elements cannot be achieved.

### DISCLOSURE OF THE INVENTION

The present invention is provided in view of the problems and a purpose of the invention is to provide a semiconductor storage device wherein storage of two bits is implemented in one transistor and that can be further miniaturized.

In order to solve the problems, there is provided a semiconductor storage device comprising:
a semiconductor substrate;
a gate insulating film formed on the semiconductor substrate;
a single gate electrode formed on the gate insulating film;
two charge holding portions formed on the sidewalls on opposite sides of the single gate electrode;
two diffusion layer regions corresponding to the two charge holding portions, respectively; and
a channel region placed beneath the single gate electrode, wherein
the charge holding portions have a structure such that a film made of a first insulator having a function of holding charge is sandwiched between a second insulator and a third insulator, and
the charge holding portions are constituted such that the amount of current flowing between one of the diffusion layer regions and the other of the diffusion layer regions at the time of application of a voltage to the gate electrode is changed due to the quantity of charge held in the first insulator.

According to the semiconductor storage device of the constitution, two charge holding portions, formed on opposite sidewalls of the gate electrode, are independent of the gate insulating film so that the memory function carried out by the charge holding portions and the transistor operation function carried out by the gate insulating film are separated. Therefore, it is easy to form the gate insulating film as a thin film so that short channel effects are suppressed while retaining a sufficient memory function. In addition, the two charge holding portions, formed on opposite sides of the gate electrode, are separated by the gate electrode and, therefore, interference at the time of rewriting can be effectively suppressed. In other words, the distance between the two charge holding portions can be reduced. Accordingly, a semiconductor storage device wherein two bit operation is possible and miniaturization is easy can be provided.

Furthermore, the semiconductor storage device has a structure such that the film made of the first insulator having the function of storing a charge is sandwiched between the second and third insulators. Therefore, charge density within the first insulator can be increased and, in addition, the charge density can be made uniform for a short period of time at the time of charge injection. Moreover, the first insulator for storing a charge is separated from conductor parts (gate electrode, diffusion layer regions, semiconductor substrate) by means of other insulating films and, therefore, charge leakage can be restricted so that a sufficient period of time for holding a charge can be obtained. Accordingly, high speed rewriting and increase in reliability become possible, and a sufficient period of time for holding a charge can be secured in the semiconductor storage device.

In one embodiment, expressions X1>X2 and X1>X3 are satisfied, where
the X1 represents an energy gap between the vacuum level and the lowest level of a conduction band of the first insulator,
the X2 represents an energy gap between the vacuum level and the lowest level of a conduction band of the second insulator, and
the X3 represents an energy gap between the vacuum level and the lowest level of a conduction band of the third insulator.

The same function and effects of the semiconductor storage device of the present invention can also be obtained according to the semiconductor storage device of the above embodiment.

Furthermore, the electron affinity of the first insulator is greater than the electron affinities of the second and third insulators. Therefore, in the case that the stored charge is of electrons, discharge from the film made of the first insulator for charge storage can be effectively suppressed so that the period of time of storage is increased. Furthermore, the efficiency of charge injection to the first insulator for charge storage is enhanced so that the period of time of rewriting is reduced. Accordingly, the period of time of rewriting of the semiconductor storage device is reduced so that high speed operation can be realized.

In one embodiment, expressions Φ1<Φ2 and Φ1<Φ3 are satisfied, where
the Φ1 represents an energy gap between the vacuum level and the highest level of a valence band of the first insulator,
the Φ2 represents an energy gap between the vacuum level and the highest level of a valence band of the second insulator, and
the Φ3 represents an energy gap between the vacuum level and the highest level of a valence band of the third insulator.

The same function and effects of the semiconductor storage device of the present invention can also be obtained according to the semiconductor storage device of the above embodiment.

Furthermore, the energy gap between the vacuum level and the highest level of the valence band of the first insulator is smaller than the energy gap between the vacuum level and the highest level of the valence band of the second or third insulator. Therefore, in the case that the stored charge is of positive holes, discharge from the film made of the first insulator for charge storage is effectively suppressed so that the period of time of storage is increased. Furthermore, the efficiency of charge injection to the first insulator for charge storage is enhanced so that the period of time of rewriting is reduced. Accordingly, the period of time of rewriting of the semiconductor storage device is reduced so that high speed operation can be realized.

In one embodiment, all expressions of: X1>X2, X1>X3, Φ1<Φ2 and Φ1<Φ3 are satisfied, where
the X1 represents an energy gap between the vacuum level and the lowest level of the conduction band of the first insulator,
the X2 represents an energy gap between the vacuum level and the lowest level of the conduction band of the second insulator,
the X3 represents an energy gap between the vacuum level and the lowest level of the conduction band of the third insulator,
the Φ1 represents an energy gap between the vacuum level and the highest level of the valence band of the first insulator,
the Φ2 represents an energy gap between the vacuum level and the highest level of the valence band of the second insulator is denoted as Φ2, and
the Φ3 represents an energy gap between the vacuum level and the highest level of the valence band of the third insulator.

The same function and effects of the semiconductor storage device of the present invention can also be obtained according to the semiconductor storage device of the above embodiment.

Furthermore, the electron affinity of the first insulator is greater than the electron affinity of each of the second and third insulators, and the energy gap between the vacuum level and the highest level of the valence band in the first insulator is smaller than the energy gap between the vacuum level and the highest level of the valence band in the second or third insulator. Therefore, the electron injection efficiency and the positive hole injection efficiency are both increased and the speeds of both the writing operation and the erasing operation can be increased in the case where, for example, electrons are injected to the first insulator at the time of writing and where positive holes are injected for recombination with stored electrons at the time of erasure (the same function can be obtained when interchanging holes and electrons).

In one embodiment, the first insulator is of silicon nitride, and the second and third insulators are of silicon oxide.

In the semiconductor storage device of the above embodiment, the first to third insulators are concretely specified in the semiconductor storage device of the present invention. The first insulator, having the function of charge storage, is a silicon nitride film wherein the hysteresis characteristics are remarkably obtained due to the existence of a great number of levels for trapping charges (electrons and positive holes). In addition, since the second and third insulators are silicon oxide films, the electron affinity of the first insulator is greater than the electron affinity of each of the second and third insulators, and the energy gap between the vacuum level and the highest level of the valence band in the first insulator is smaller than the energy gap between the vacuum level and the highest level of the valence band in each of the second and third insulators. Accordingly, the speeds of both the writing operation and the erasing operation can be increased. Furthermore, both silicon oxide films and silicon nitride films are made of materials used in standard LSI manufacturing processes and, therefore, the manufacturing process of the above embodiment is simple.

In one embodiment, the second insulator that is of silicon oxide is in a film form and separates the semiconductor substrate from the first insulator, and the film formed of the second insulator on the semiconductor substrate has a thickness of no less than 1.5 nm and of no greater than 15 nm.

According to the semiconductor storage device of the above embodiment, charge injection to the first insulator can be carried out at a sufficiently high speed while leakage of the charge stored in the first insulator is suppressed. Accordingly, a semiconductor storage device can be provided wherein a high speed rewrite operation and a sufficient period of time of storage are both obtained.

In one embodiment, the film formed of the first insulator, which is of silicon nitride, on the semiconductor substrate has a thickness of no less than 2 nm and of no greater than 15 nm.

Difference in the threshold values (or the level of the read-out current) of the semiconductor storage device of the above embodiment is made sufficiently great and, thereby, dispersion among elements is suppressed and, in addition, change in the threshold value due to charge shift in the silicon nitride film in which data is stored can be suppressed.

In one embodiment, the second insulator is in a film form and separates the semiconductor substrate and the sidewalls of the gate electrode from the first insulator, and
the thickness of the film made of the second insulator in the vicinity of the sidewalls of the gate electrode is greater than the thickness of the film made of the second insulator on the semiconductor substrate.

The same function and effects of the semiconductor storage device of the present invention can also be obtained according to the semiconductor storage device of the above embodiment.

Furthermore, the thickness of the film made of the second insulator in the vicinity of the sidewalls of the gate electrode is greater than the thickness of the film made of the second insulator on the semiconductor substrate and, therefore, electron injection from the gate electrode to the first insulator for charge storage (or release of charge from the first insulator to the gate electrode) can be effectively suppressed. Accordingly, the rewrite characteristics of the semiconductor storage device are stable and the reliability is increased.

In one embodiment, the thickness of the film made of the second insulator on the semiconductor substrate is less than the thickness of the gate insulating film and is not less than 0.8 nm.

According to the semiconductor storage device of the above embodiment, the thickness of the film made of the second insulator on the semiconductor substrate is less than the thickness of the gate insulating film and is no less than 0.8 nm and, thereby, it becomes possible to maintain the uniformity of the films and a constant level of film quality in the manufacturing process and, in addition, it becomes possible to lower the voltage for the writing operation and the erasing operation and to increase the speeds of the writing operation and the erasing operation, while preventing the storage characteristics from deteriorating to a great extent, without lowering the memory performance or resistance to voltage and it also becomes possible to increase the memory performance.

In one embodiment, the thickness of the film made of the second insulator on the semiconductor substrate is greater than the thickness of the gate insulating film and is not greater than 20 nm.

According to the semiconductor device of the above embodiment, the thickness of the film made of the second insulator on the semiconductor substrate is greater than the thickness of the gate insulating film and is not greater than 20 nm and, thereby, it becomes possible to improve the storage characteristics without slowing the rewrite speed to a great extent or without deteriorating the short channel effects of the memory.

In one embodiment, at least a portion of the film made of the first insulator having a function of charge storage overlaps a portion of the diffusion layer regions.

According to the semiconductor device of the above embodiment, at least a portion of the film made of the first insulator having the function of charge storage is formed so as to be overlapped with a portion of the diffusion layer regions and, thereby, the speed of the read-out operation can be increased.

In one embodiment, the film made of the first insulator having a function of charge storage includes a portion having a surface approximately parallel to the surface of the gate insulating film.

According to the semiconductor device of the above embodiment, the film made of the first insulator having the function of charge storage includes a portion having a surface approximately parallel to the surface of the gate insulating film and, therefore, the memory performance due to the quantity of charge stored in the film made of the first insulator having the function of charge storage can be effectively controlled and, thereby, the memory performance can be enhanced. Furthermore, shift of charge in the upward direction can be suppressed in the film made of the first insulator having the function of charge storage so that change in characteristics due to charge shift can be prevented from occurring while data is stored.

In one embodiment, the film made of the first insulator having a function of charge storage includes a portion that extends approximately parallel to sides of the gate electrode.

According to the semiconductor device of the above embodiment, the film made of the first insulator having the function of charge storage includes a portion extending approximately parallel to the sides of the gate electrode and, therefore, the amount of charge injected to the film made of the first insulator having the function of charge storage increases at the time of the rewrite operation and, thereby, the rewrite speed is increased.

### BRIEF DESCRIPTION OF THE DRAWINGS

FIG. 1 is a schematic cross sectional view showing the main portion of a semiconductor storage device according to one embodiment of the present invention;

FIG. 2 is an enlarged schematic cross sectional view showing a portion of the semiconductor storage device according to the embodiment of the present invention;

FIG. 3 is a diagram showing energy bands along the cross section of line A-A′ of FIG. 2;

FIGS. 4A and 4B are schematic cross sectional views showing the main portion for describing the writing operations of the semiconductor storage device according to the embodiment of the present invention;

FIG. 5 is a schematic cross sectional view showing the main portion for describing the first erasure operation of the semiconductor storage device according to the embodiment of the present invention;

FIG. 6 is a schematic cross sectional view showing the main portion for describing the second erasure operation of the semiconductor storage device according to the embodiment of the present invention;

FIGS. 7A, 7B and 7C are schematic cross sectional views showing the main portion, according to manufacturing steps, for describing a manufacturing method for the semiconductor storage device according to the embodiment of the present invention;

FIG. 8 is a schematic cross sectional view of the main portion showing a semiconductor storage device according to one embodiment of the present invention;

FIGS. 9A, 9B and 9C are schematic cross sectional views showing the main portion, according to manufacturing steps, for describing a manufacturing method for the semiconductor storage device according to the embodiment of the present invention;

FIG. 10 is a schematic cross sectional view showing the main portion showing a semiconductor storage device according to one embodiment of the present invention;

FIG. 11 is an enlarged schematic cross sectional view showing a portion of the semiconductor storage device according to the embodiment of the present invention;

FIG. 12 is an enlarged schematic cross sectional view showing a portion of a modification of the semiconductor storage device according to the embodiment of the present invention;

FIG. 13 is a graph showing the relationship between the offset amount W1, between the gate electrode and the diffusion layer regions, and drain current Id in the semiconductor storage device of the present invention;

FIG. 14 is an enlarged schematic cross sectional view showing a portion of another modification of the semiconductor storage device according to the embodiment of the present invention;

FIG. 15 is a schematic cross sectional view for describing the effects of the semiconductor storage device according to the embodiment of the present invention;

FIG. 16 is a schematic cross sectional view showing the main portion of a semiconductor storage device according to one embodiment of the present invention;

FIG. 17 is a schematic cross sectional view showing the main portion of a semiconductor storage device according to one embodiment of the present invention;

FIG. 18 is a schematic cross sectional view showing the main portion of a semiconductor storage device according to one embodiment of the present invention;

FIG. 19 is a schematic cross sectional view showing the main portion of a semiconductor storage device according to one embodiment of the present invention;

FIG. 20 is a schematic cross sectional view showing the main portion of a semiconductor storage device according to one embodiment of the present invention; and

FIG. 21 is a cross sectional schematic view showing the main portion of a semiconductor storage device according to a prior art.

### BEST MODE FOR CARRYING OUT THE INVENTION

A semiconductor storage device of the present invention is mainly formed of a gate insulating film, a gate electrode formed on the gate insulating film, charge holding portions formed on both sides of the gate electrode, source/drain regions (diffusion layer regions), respectively, placed on the each side of the charge holding portions opposite to the gate electrode and a channel region placed beneath the gate electrode.

This semiconductor storage device functions as a memory element for storage of data of four, or more, values by storing data of two, or more, values in one charge holding portion.

It is preferable for the semiconductor storage device of the present invention to be formed in a semiconductor substrate or, in particular, in a well region of a first conductive type formed within a semiconductor substrate.

The semiconductor substrate is not particularly limited as long as it can be utilized for manufacturing a semiconductor device and, for example, various types of substrates, such as substrates made of an element semiconductor, such as of silicon, germanium, or the like, made of a compound semiconductor, such as of GaAs, InGaAs, ZnSe, or the like, or an SOI substrate or a multi-layer SOI substrate can be used. In particular, a silicon substrate or an SOI substrate having a silicon layer formed as a surface semiconductor layer are preferable. Preferably, element isolation regions are formed in such a semiconductor substrate and, furthermore, a single, or multi-layer, structure may be formed wherein elements such as transistors, capacitors and resistors, circuits made of these elements, semiconductor devices and interlayer insulating films are combined. Here, the element isolation regions can be formed of various types of element isolation films such as LOCOS films, trench oxide films or STI films. The semiconductor substrate may be of a P conductive type or an N conductive type and it is preferable for at least one well region of a first conductive type (P type or N type) to be formed in the semiconductor substrate. The range of impurity concentration known in the field of the art can be utilized in the semiconductor substrate and in the well region. Here, in the case wherein an SOI substrate is used for the semiconductor substrate, a well region may be formed in the surface semiconductor layer and there may be a body region beneath the channel region.

The gate insulating film is not particularly limited, as long as it is utilized in a conventional manner in the semiconductor device and, for example, insulating films such as a silicon oxide film or a silicon nitride film, single-layer, or multi-layer, high dielectric films such as an aluminum oxide film, a titanium oxide film, a tantalum oxide film or a hafnium oxide film can be utilized for the gate insulating film. In particular, a silicon oxide film is preferable.

The gate electrode is formed in a conventionally utilized form on the gate insulating film in a semiconductor device. The material of the gate electrode is not particularly limited, unless otherwise specified in the embodiment and a conductive film, such as of polysilicon, metal films, such as of copper or of aluminum, high melt point metal films, such as of tungsten, of titanium or of tantalum, a single-layer film, or a multi-layer film, such as of a high melt point metal or of silicide, can be cited. It is appropriate to form the gate electrode so as to have a film thickness of approximately 50 nm to 400 nm. Here, a channel region is formed beneath the gate electrode and it is preferable for the channel region to be formed beneath the region including the regions outside of the edges of the gate in the gate length direction, in addition to the region beneath the gate electrode. In the case wherein there are portions of the channel region that are not covered by the gate electrode as described above, it is preferable for such a channel region to be covered with a gate insulating film or with charge holding portions as described below.

It is preferable for a charge holding portion to have a sandwich structure wherein a film made of a first insulator for charge storage is placed between a film made of a second insulator and a film made of a third insulator. Since the first insulator for charge storage is in a film form, the charge density within the first insulator can be increased for a short period of time by means of charge injection and the charge density can be made uniform. In the case that the charge distribution within the first insulator for charge storage is not uniform, there is a risk that the stored charge may shift within the insulator, lowering the reliability of the memory element. In addition, the first insulator for charge storage is separated from conductive parts (gate electrode, diffusion layer regions, semiconductor substrate) by another insulating film and, therefore, a sufficient period of time of storage can be obtained by suppressing charge leakage. Accordingly, in the case that the semiconductor storage device has the sandwich structure, high speed rewrite and increase in reliability become possible, and a sufficient period of time of storage can be secured in the semiconductor storage device.

Furthermore, in the case that the storage charge is of electrons, it is preferable for the electron affinity of the first insulator to be greater than each of the electron affinities of the second and third insulators. Here, the electron affinity means the energy gap between the vacuum level and the lowest level of the conduction band. Alternately, in the case that the stored charge is of positive holes, it is preferable for the energy gap between the vacuum level and the highest level of the valence band of the first insulator to be smaller than the energy gap between the vacuum level and the highest level of the valence band of each of the second and third insulators. Discharge from the film made of the first insulator for charge storage can be effectively suppressed and the period of time of storage can be increased in the case that the conditions are satisfied. Furthermore, the charge injection efficiency to the first insulator for charge storage is increased and the period of time for rewriting is reduced. In order to satisfy the conditions for charge holding portions, it is particularly preferable for the first insulator to be a silicon nitride film and for the second and third insulators to be silicon oxide films. A great number of levels for trapping charges exist in a silicon nitride film and, therefore, the hysteresis characteristics are pronounced. In addition, silicon oxide films and silicon nitride films are both used in standard LSI manufacturing processes and, therefore, usage thereof is preferable. In addition, hafnium oxide, tantalum oxide, yttrium oxide, and the like, in addition to silicon nitride, can be used as the first insulator. Furthermore, aluminum oxide, or the like, in addition to silicon oxide, can be used as the second and third insulators. Here, the second and third insulators may be of different materials or may be of the same material.

Charge holding portions are formed on each side of the gate electrode and are placed above the semiconductor substrate (well region, body region, source/drain regions or diffusion layer regions).

The source/drain regions, respectively, are placed on the side of the charge holding portions opposite to the gate electrode as diffusion layer regions of the conductive type opposite to that of the semiconductor substrate or the well region. It is preferable for the junctions between the source/drain regions and the semiconductor substrate, or the well region, to have a sharp shift in impurity concentration. This is because hot electrons or hot positive holes are efficiently generated at a low voltage, allowing high speed operation at a low voltage. The depth of the junctions of the source/drain regions are not particularly limited but, rather, can be appropriately adjusted in accordance with the performance, and the like, of the semiconductor storage device to be obtained. Here, in the case that an SOI substrate is used as the semiconductor substrate, the depth of the junctions of the source/drain regions may be less than the film thickness of the surface semiconductor layer and is preferably approximately the same as the film thickness of the surface semiconductor layer.

The source/drain regions may be placed so as to overlap the edges of the gate electrode or may be placed so as to be offset relative to the edges of the gate electrode. In particular, in the case of being offset, the ease of inversion of the offset regions beneath the charge holding portions at the time of application of a voltage to the gate electrode varies greatly due to the amount of charge stored in the charge holding portions and, thereby, the memory effects are increased and the short channel effects are reduced, which is preferable. Here, in the case that the amount of offset is too great, a drive current between the source and drain is significantly reduced. Accordingly, the amount of offset should be determined so that the memory effects and the drive current both have appropriate values.

Portions of the source/drain regions may extend to the surface of the channel region, that is to say, to positions higher than the lower surface of the gate insulating film. In this case, a conductive film is integrally layered on the source/drain regions formed within the semiconductor substrate in an appropriate configuration. As for the material of the conductive film, semiconductors such as polysilicon or amorphous silicon, a silicide, metals or high melt point metals as described above can be cited. In particular, polysilicon is preferable. This is because the impurity diffusion rate in polysilicon is much greater than that of a semiconductor substrate and, therefore, it is easy to make the depth of the junctions of the source/drain regions shallow within the semiconductor substrate so that the short channel effects can easily be suppressed. Here, in this case, it is preferable to place these portions of the source/drain regions so that at least some portions of the charge storage film are sandwiched between these portions of the source/drain regions and the gate electrode.

The semiconductor storage device of the present invention has four terminals: a single gate electrode formed on the gate insulating film, the source region, the drain region and the semiconductor substrate, and carries out write-in, erasure and read-out operations, respectively, by providing predetermined potentials to the four terminals, respectively. Concrete principles of operation and examples of operational voltages are described below. In the case that a memory cell array is formed by placing the semiconductor storage devices of the present invention in an array form, a plurality of memory cells can be controlled by a single control gate so that the number of word lines can be reduced.

The semiconductor storage device of the present invention can be formed according to a conventional semiconductor manufacturing process, for example, according to the same method as the method for forming sidewall spacers of a layered structure on the sidewalls of a gate electrode. Concretely, a method can be cited wherein film layers made up of an insulating film (second insulator)/charge storage film (first insulator)/insulating film (second insulator) after the formation of a gate electrode and, then, etch back is carried out under appropriate conditions so that these films remain in the form of sidewall spacers.

In the case that a memory cell array is formed through arrangement of the semiconductor storage devices of the present invention, the semiconductor storage device according to the best mode of the invention satisfies all of the following requirements: (1) gate electrodes of a plurality of semiconductor storage devices are integrated to have the function of a word line, (2) charge holding portions are formed on each side of the word line, (3) an insulator, in particular a silicon nitride film, holds a charge within a charge holding portion, (4) charge holding portions are formed of an ONO (Oxide Nitride Oxide) film wherein the silicon nitride film has a surface approximately parallel to the surface of the gate insulating film, (5) the silicon nitride film in a charge holding portion is separated from the word line and the channel region by the silicon oxide film, (6) the silicon nitride film within a charge holding portion and a diffusion region overlap each other, (7) the thickness of the insulating film that separates the silicon nitride film, having a surface approximately parallel to the surface of the gate insulating film, from the channel region, or from the semiconductor layer, differs from the thickness of the gate insulating film, (8) the write-in and erasure operations for one semiconductor storage device are carried out using a single word line, (9) the electrode (word line), which has a function of assisting the write-in and erasure operations, does not exist above charge holding portions and (10) the semiconductor storage device has regions with a high concentration of an impurity of the conductive type opposite to that of the diffusion regions in the portions contacting the diffusion regions directly beneath the charge holding portions. Here, a semiconductor storage device that satisfies any one of these requirements is considered to be an embodiment of the present invention.

A particularly preferable combination of the requirements is, for example, a case wherein (3) an insulator, in particular a silicon nitride film, holds a charge within a charge holding portion, (6) the insulating film (silicon nitride film) within a charge holding portion and a diffusion region overlap each other and (9) the electrode (word line), which has a function of assisting the write-in and erasure operations, does not exist above charge holding portions.

In the case that requirements (3) and (9) are satisfied, a very advantageous semiconductor storage device is obtained as follows.

First, bit line contacts can be placed close to a charge holding portion on the word line sidewall and charge holding portions, making up a plurality, are prevented from interfering with each other so that data storage can be maintained even in the case that the distance between the semiconductor storage devices is reduced. Accordingly, miniaturization of the semiconductor storage device becomes easy. Here, in the case that charge storage regions within charge holding portions are conductors, interference between charge storage regions occur due to capacitance coupling as the semiconductor storage devices become closer to each other so that storage of data cannot be maintained.

In addition, in the case that the charge storage regions within charge holding portions are insulators (for example, silicon nitride film), it becomes unnecessary to make independent charge holding portions for each memory cell. For example, charge holding portions, formed on each side of one word line shared by a plurality of memory cells, need not be separated according to each memory cell and it becomes possible to share charge holding portions formed on each side of one word line by a plurality of memory cells that share the word line. Therefore, a photographic and etching process for separating the charge holding portions becomes unnecessary and the manufacturing process is simplified. Furthermore, a margin for positioning in the photolithographic process and an over etching margin for films become unnecessary so that the margin between memory cells can be reduced. Accordingly, the area occupied by the memory cells can be miniaturized even when the memory cells are formed according to the same level of microscopic processing in comparison with the case wherein the charge holding portions within charge holding portions are conductors (for example, polycrystal silicon film). Here, in the case that the charge holding portions within charge holding portions are conductors, a photographic and etching process for separating the charge holding portions every memory cells becomes necessary and a margin for positioning the photomask and an over etching margin for films become necessary.

Furthermore, no electrodes having the function of assisting the write-in and erasure operations exist on top of the charge holding portions and, therefore, the structure of the element is simple so that the number of manufacturing steps can be reduced and the yield can be increased. Accordingly, the semiconductor storage devices can easily be formed together with the transistors for forming logic circuits and analog circuits and, at the same time, the cost of the semiconductor storage device can be reduced.

In addition, in the case wherein requirement (6) is satisfied, in addition to requirements (3) and (9), a more advantageous semiconductor storage device can be obtained.

That is to say, charge storage regions within charge holding portions and diffusion regions overlap each other and, thereby, write-in and erasure at a very low voltage become possible. Concretely, the write-in and erasure operations can be carried out at the low voltage of no greater than 5 V. It is very advantageous to use this property in circuit design. Since it becomes unnecessary to utilize a high voltage within a chip, unlike in the case of a flash memory, it becomes possible to omit or to scale down the charge pumping circuit, which occupies a large area. In particular, in the case that a memory having a small-scale capacity is built into a logic LSI for adjustment, the area occupied by the memory part is dominated by the periphery circuits for driving the memory cells rather than by the memory cells and, therefore, the omission or scaling down of a booster circuit for memory cells is most effective in order to reduce chip size.

On the other hand, in the case wherein requirement (3) is not satisfied, that is to say, in the case wherein a conductor stores a charge within a charge holding portion, the write-in operation can be carried out even when requirement (6) is not satisfied, that is to say, when the conductor within a charge holding portion and the diffusion region do not overlap. This is because the conductor within the charge holding portion assists write-in due to capacitance coupling vis-à-vis the gate electrode.

In addition, in the case wherein requirement (9) is not satisfied, that is to say, in the case wherein an electrode having the function of assisting the write-in and erasure operations exists on top of a charge holding portion, the write-in operation can be carried out even when requirement (6) is not satisfied, that is to say, when the insulator within a charge holding portion and the diffusion region do not overlap.

In semiconductor storage device of the present invention transistors may be connected in series to one side or to both sides of the semiconductor storage device and the semiconductor storage device may be formed on the same chip as are logic transistors. In such a case, the semiconductor device, in particular, the semiconductor storage device, of the present invention, can be formed according to a process having a very high similarity to the manufacturing process for conventional transistors, including standard transistors and logic transistors and, therefore, they can be manufactured at the same time. Accordingly, a process for manufacturing a semiconductor storage device and logic transistors and other types of transistors on the same chip is greatly simplified so that an a device that includes a storage device as well as other semiconductor devices can be obtained at a low cost.

In the semiconductor storage device of the present invention one charge holding portion can store data of two, or more, values and, thereby, the semiconductor storage device can function as a memory cell that stores data of four, or more, values. Here, the semiconductor storage device may be used for the storage of data of two values. In addition, the semiconductor storage device can function as a memory cell having the functions of both a selection transistor as well as a memory transistor by using the variable resistance effect created by charge holding portions.

The semiconductor storage device of the present invention can be used in a battery operated portable electronic device, in particular a portable data terminal. As for portable electronic devices, a portable data terminal, a cellular phone, a game device, and the like, can be cited.

In the following, the semiconductor storage device of the present invention is described in detail in reference to the drawings.

### Embodiment 1

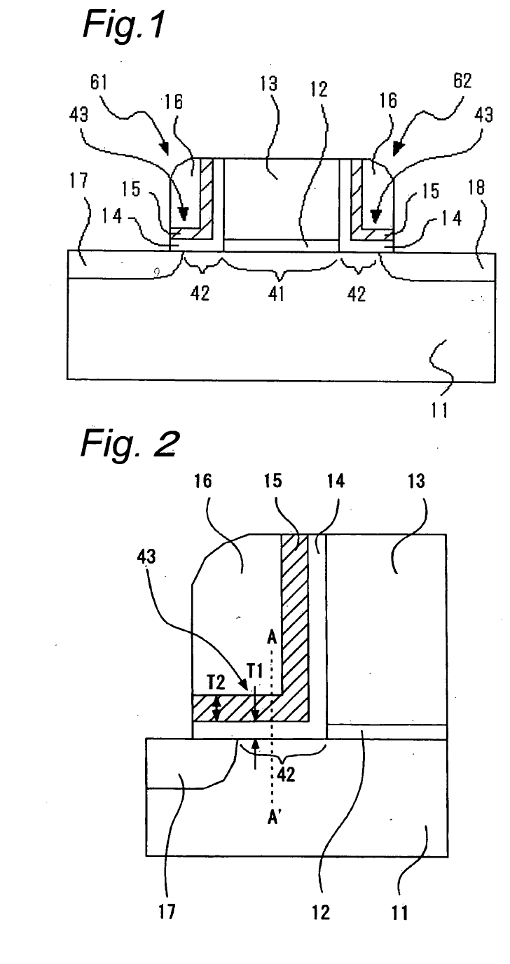

In a memory element forming a semiconductor storage device of the present embodiment as shown in FIG. 1, a gate electrode 13 having a gate length of approximately the same length as a conventional transistor, for example from approximately 0.015 μm to 0.5 μm, is formed above a semiconductor substrate 11 via a gate insulating film 12 and charge holding portions 61 and 62 in the form of sidewall spacers are formed on the gate insulating film 12 and on the sidewalls of gate electrode 13 so as to form a non-volatile memory cell that allows the storage of two bits. In addition, first and second diffusion layer regions 17 and 18 (source/drain regions) are formed on the side of charge holding portions 61 and 62 opposite to gate electrode 13 wherein these charge holding portions 17 and 18 are offset relative to the edges of gate electrode 13 (offset from region 41 on which gate electrode 13 is formed).

As described above, charge holding portions 61 and 62 of the memory transistor are formed independently of gate insulating film 12. Accordingly, the memory function carried out by charge holding portions 61 and 62 is separated from the transistor operation function carried out by gate insulating film 12. In addition, two charge holding portions 61 and 62, formed on opposite sides of gate electrode 13, are separated from each other by gate electrode 13 and, thereby, interference at the time of rewriting can be effectively restricted. Accordingly, this memory transistor allows storage of two bits and miniaturization thereof is easy.

In addition, source/drain regions 17 and 18 are offset from gate electrode 13 and, thereby, the ease of inversion in offset regions 42 beneath charge holding portions 61 at the time of the application of a voltage to gate electrode 13 can be greatly altered according to the amounts of the charges stored in charge holding portions 61 and 62 so that it becomes possible to increase the memory effects. Furthermore, the short channel effects can be largely prevented in comparison with a conventional logic transistor so that further reduction in the gate length can be achieved. In addition, the structure of this memory transistor is appropriate for suppression of short channel effects and a gate insulating film having a great thickness in comparison with that of a logic transistor can be adopted wherein it becomes possible to increase reliability.

Charge holding portions 61 and 62 in the form of sidewall spacers have a structure wherein a silicon nitride film 15, as an example of a film made of a first insulator, is sandwiched between a silicon oxide film 14, as an example of a film made of a second insulator, and a silicon oxide film 16, as an example of a film made of a third insulator. Silicon nitride film 15 has a function of trapping and storing a charge (electrons or positive holes). Charges are primarily stored in portions (regions 43) in silicon nitride film 15 above offset regions 42. As described above, charge holding portions 61 and 62 have a structure wherein silicon nitride film 15 is sandwiched between silicon oxide films 14 and 16 and, therefore, the charge injection efficiency to charge holding portions 61 and 62 is increased so as to achieve a high-speed rewrite operation (write-in and erasure operations).

It is preferable for at least some portions of silicon nitride film 15 to be formed so as to overlap portions of first and second diffusion layer regions 17 and 18.

In addition, it is preferable for silicon nitride film 15 to include a portion having a surface approximately parallel to the surface of gate insulating film 12.

In addition, it is preferable for silicon nitride film 15 to include a portion that extends approximately parallel to the sides of gate electrode 12.

FIG. 2 is an enlarged view of a portion of the memory element shown in FIG. 1 in the vicinity of one of the edges of the gate. Since regions 43 primarily store charges, thickness T1 of silicon oxide film 14 and thickness T2 of silicon nitride film 15 above offset region 42 have a great effect on the memory characteristics.

It is preferable to set thickness T1 of silicon oxide film 14 above offset region 42 as follows. In the case that thickness T1 of silicon oxide film 14 is 1.5 nm, or less, the charge stored in region 43 easily escapes through silicon oxide film 14 and, therefore, the period of time of storage is significantly shortened. On the other hand, in the case that thickness T1 is 15 nm, or greater, the charge injection efficiency to region 43 is lessened and the period of time of write-in increases to an extent that cannot be ignored. Accordingly, it is preferable for thickness T1 of silicon oxide film 14 to be in the range of from 1.5 nm to 15 nm in order to provide both a sufficient period of time of storage as well as high-speed rewrite. It is more preferable for T1 to be in the range of from 5 nm to 12 nm.

It is preferable to set thickness T2 of silicon nitride film 15 above offset region 42 as follows. In the case that thickness T2 of silicon nitride film 15 is 2 nm, or less, the charge trap density included in silicon nitride film 15 becomes insufficient and, therefore, the change in the threshold value (or change in the read-out current) of the memory element becomes insufficient. Furthermore, dispersion among elements resulting from dispersion in the film thickness of silicon nitride film 15 becomes too great to be ignored. On the other hand, in the is case that thickness T2 of silicon nitride film is 15 nm, or greater, it becomes difficult to uniformly inject charges into the silicon nitride film at the time of rewriting, or a long period of time becomes necessary. In addition, in the case that charges are not uniformly injected into the silicon nitride film 15, charges shift in the silicon nitride film 15 while data is being stored so that the change in the threshold value (or read-out current) becomes problematic. Accordingly, it is preferable for thickness T2 of silicon nitride film 15 to be in the range of from 2 nm to 15 nm in order to provide a sufficient reliability to the memory element. It is more preferable for T2 to be in the range of from 3 nm to 7 nm.

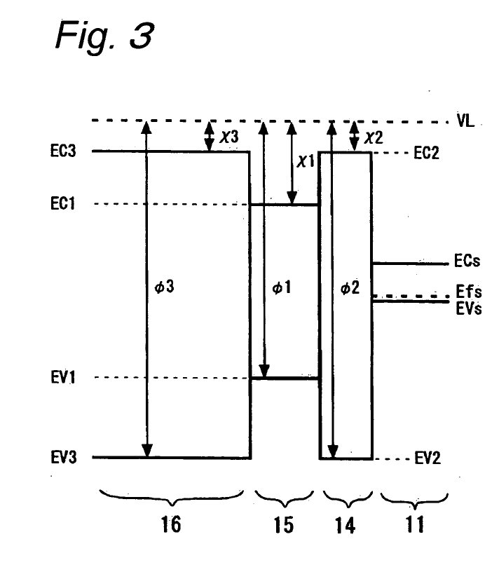

FIG. 3 shows an energy diagram (energy band diagram) of electrons in the cross section along line A-A′ of FIG. 2. Here, the bands are all posited as being flat (vacuum level VL is constant regardless of position) for the purpose of simplicity. In FIG. 3, the lowest level of the conductive band of the semiconductor (semiconductor substrate 11) is denoted as ECs, the highest level of the valence band of the semiconductor is denoted as EVs, the Fermi level of the semiconductor is denoted as Efs, the lowest level of the conductive band of the first insulator (silicon nitride film 15) is denoted as EC1, the highest level of the valence band of the first insulator is denoted as EV1, the lowest level of the conductive band of the second insulator (silicon oxide film 14) is denoted as EC2, the highest level of the valence band of the second insulator is denoted as EV2, the lowest level of the conductive band of the third insulator (silicon oxide film 16) is denoted as EC3 and the highest level of the valence band of the third insulator is denoted as EV3. Accordingly, the energy gap (electron affinity force) between the vacuum level and the lowest level of the conductive band of the first insulator is denoted as X1, the energy gap between the vacuum level and the highest level of the valence band of the first insulator is denoted as Φ1, the energy gap (electron affinity force) between the vacuum level and the lowest level of the conductive band of the second insulator is denoted as X2, the energy gap between the vacuum level and the highest level of the valence band of the second insulator is denoted as Φ2, the energy gap (electron affinity force) between the vacuum level and the lowest level of the conductive band of the third insulator is denoted as X3 and the energy gap between the vacuum level and the highest level of the valence band of the third insulator is denoted as Φ3.

In the case wherein electrons are stored in the first insulator for charge storage, X1>X2 and X1>X3 is preferable. In this case, the third insulator (silicon oxide film 16) becomes a barrier increasing the electron injection efficiency at the time of injection of electrons into the first insulator (silicon nitride film 15). In addition, electrons stored in the first insulator can be efficiently prevented from leaking to semiconductor substrate 11. Accordingly, a high-speed write-in operation and good storage characteristics can be obtained.

In the case wherein positive holes are stored in the first insulator for charge storage, Φ1<Φ2 and Φ1<Φ3 is preferable. In this case, the third insulator (silicon oxide film 16) becomes a barrier increasing the positive hole injection efficiency at the time of injection of positive holes into the first insulator (silicon nitride film 15). In addition, positive holes stored in the first insulator can be efficiently prevented from leaking to semiconductor substrate 11. Accordingly, a high-speed write-in operation and good storage characteristics can be obtained.

Here, it is more preferable for all the four conditions (X1>X2, X1>X3, Φ1<Φ2 and Φ1<Φ3) to be satisfied. In the case wherein electrons are stored in the first insulator for charge storage, for example, the positive hole injection efficiency becomes high when positive holes are injected in order to remove the stored electrons so that the erasure operation can be carried out at high speed.

Though in the present embodiment the first insulator is a silicon nitride film and the second and third insulators are silicon oxide films, the invention is not limited to this. For example, the first insulator can be made of a high dielectric material such as of hafnium oxide, tantalum oxide, yttrium oxide, zirconium oxide, or the like. Furthermore, the second and third insulators can be made of aluminum oxide.

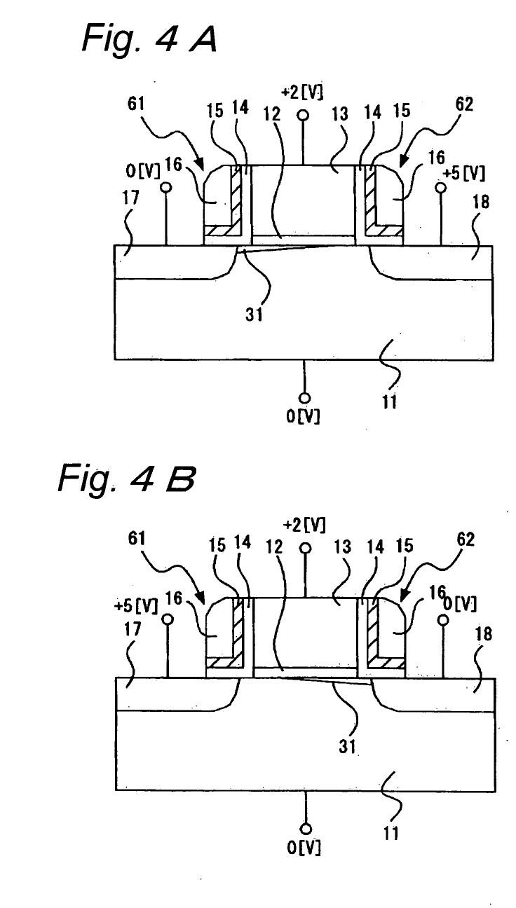

The principle of the write-in operation of this memory is described in reference to FIGS. 4A and 4B.

Here, write-in indicates injection of electrons into charge holding portion 61 or 62.

In order to inject electrons (write-in) into second charge holding portion 62, as shown in FIG. 4A, first diffusion layer region 17 is used as the source electrode and the second diffusion layer region 18 is used as the drain electrode. For example, 0V is applied to first diffusion layer region 17 and to semiconductor substrate 11, +5V is applied to second diffusion layer region 18 and +2V is applied to gate electrode 13. Under such voltage conditions, inversion layer 31 extends from first diffusion layer region 17 (source electrode) and does not reach to second diffusion layer region 18 (drain electrode) so that a pinch off point occurs. Electrons are accelerated from the pinch off point to second diffusion layer region 18 (drain electrode) by means of a high electrical field so as to become so-called hot electrons (conductive electrons of a high energy). These hot electrons are injected into second charge holding portion 62 (more precisely silicon nitride film 15) and, thereby, write-in is carried out. Here, hot electrons are not generated in the vicinity of first charge holding portion 61 and, therefore, write-in is not therein carried out.

As described above, write-in can be carried out by injecting electrons into second charge holding portion 62.

On the other hand, in order to inject electrons (write-in) into first charge holding portion 61, as shown in FIG. 4B, second diffusion layer region 18 is used as the source electrode and first diffusion layer region 17 is used as the drain electrode. For example, 0V is applied to second diffusion layer region 18 and to semiconductor substrate 11, +5V is applied to first diffusion layer region 17 and +2V is applied to gate electrode 13. The source/drain regions are switched vis-à-vis the case wherein electrons are injected into second charge holding portion 62 in the manner and, thereby, electrons are injected into first charge holding portion 61 so that write-in can be carried out.

Next, the principle of the read-out operation of the memory element is described.

In the case that data stored in first charge holding portion 61 is read-out, first diffusion layer region 17 is used as the source electrode and the second diffusion layer region 18 is used as the drain electrode so that the transistor is operated in the saturation region. For example, 0V is applied to first diffusion layer region 17 and to semiconductor substrate 11, +2V is applied to second diffusion layer region 18 and +1V is applied to gate electrode 13. At this time, the drain current easily flows in the case that electrons are not stored in first charge holding portion 61. On the other hand, the drain current does not easily flow because the inversion layer is not easily formed in the vicinity of first charge holding portion 61 in the case wherein electrons are stored in first charge holding portion 61. Accordingly, the data stored in first charge holding portion 61 can be read out by detecting the drain current. At this time, the existence of a charge stored in second charge holding portion 62 does not affect the drain current because the inversion layer is pinched off in the vicinity of the drain.

In the case wherein data stored in second charge holding portion 62 is read out, second diffusion layer region 18 is used as the source electrode and first diffusion layer region 17 is used as the drain electrode so that the transistor operates in the saturation region. For example, 0V is applied to second diffusion layer region 18 and to semiconductor substrate 11, +2V is applied to first diffusion layer region 17 and +1V is applied to gate electrode 13. The source/drain regions are switched vis-à-vis the case wherein data stored in first charge holding portion 61 is read out in the manner and, thereby, the data stored in second charge holding portion 62 can be read out.

As is clear from the above description, when focusing on a charge holding portion on one side, the source and drain are switched from the cases wherein write-in is carried out and wherein a read-out operation is carried out. In other words, the relationship between the magnitudes of the voltages applied to the first diffusion layer region and to the second diffusion layer region at the time of the read-out operation is reversed vis-à-vis at the time of the write-in operation. Therefore, the data stored in the two charge holding portions, respectively, can be detected in a highly precise manner.

Here, in the case wherein portions of the channel region (offset regions 42) are left uncovered by gate electrode 13, the inversion layer disappears or is formed according to the presence or absence of excess electrons in charge holding portions 61 and 62 resulting in a pronounced hysteresis (great change in the threshold value) in the portions of the channel region not covered by gate electrode 13. Here, in the case that the width of offset regions 42 is too great, the drain current is greatly decreased so that the speed of read-out is greatly slowed. Accordingly, it is preferable to determine the width of offset regions 42 in order to obtain a sufficient hysteresis and a high read-out speed.

In the case that first and second diffusion layer regions 17 and 18 reach to the edges of gate electrode 13, that is to say, in the case wherein first and second diffusion layer regions 17 and 18 and gate electrode 13 overlap each other, the parasitic resistances at the source/drain edges greatly differ from the above case and the drain current is greatly reduced (by one order, or greater) in comparison with the above case although the threshold value of the transistor at the time of the write-in operation does not greatly differ from the above case. Accordingly, read-out is possible through detection of the drain current so that the memory function can be obtained. Here, in the case when a greater memory hysteresis effect is required, it is preferable for gate electrode 13 not to overlap first and second diffusion layer regions 17 and 18 (offset regions 42 exist).

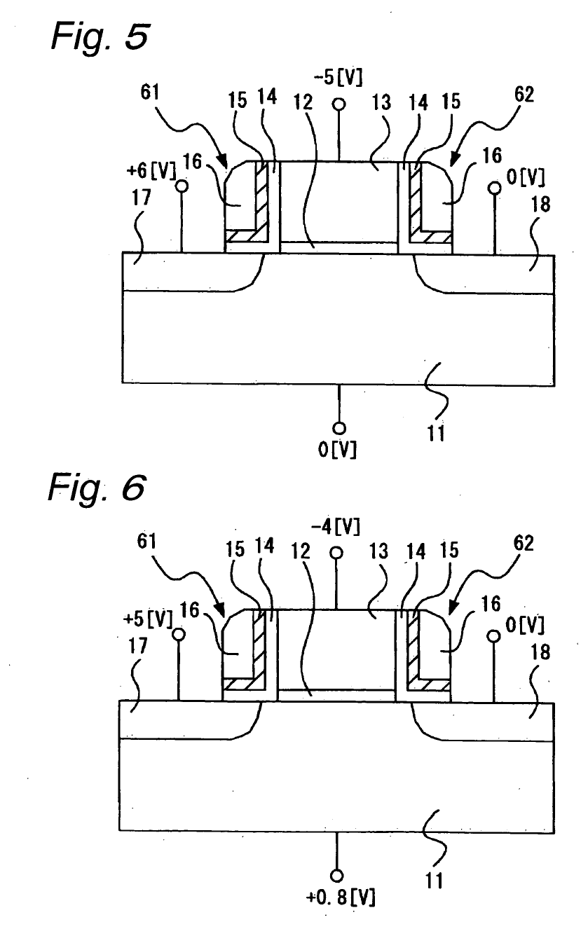

Furthermore, the principle of the erasure operation of the above semiconductor storage device is described in reference to FIG. 5.

First, in the case that data stored in first charge holding portion 61 is erased according to the first method, a positive voltage (for example, +6V) is applied to first diffusion layer region 17 and 0V is applied to semiconductor substrate 11 so that a reverse bias is applied to the PN junction between first diffusion layer region 17 and, in addition, semiconductor substrate 11 and a negative voltage (for example, −5V) is applied to gate electrode 13. At this time, the potential gradient of the portion of the PN junction in the vicinity of gate electrode 13 becomes particularly steep due to the effects of the gate electrode to which the negative voltage is applied. Therefore, hot positive holes (positive holes of high energy) are generated on the semiconductor substrate 11 side of the PN junction due to tunneling between bands. These hot positive holes are attracted in the direction toward gate electrode 13, which has a negative potential and, as a result, positive hole injection is carried out to first charge holding portion 61. As described above, erasure is carried out in first charge holding portion 61. At this time, 0V is applied to second diffusion layer region 18.

In the case wherein data stored in second charge holding portion 62 is erased, the potentials of the first and second diffusion layer regions in the above description may be switched with each other.

In the case wherein data stored in first charge holding portion 61 is erased, as shown in FIG. 6, according to the second method, a positive voltage (for example, +5V) is applied to first diffusion layer region 17, 0V is applied to second diffusion layer region 18, a negative voltage (for example, −4V) is applied to gate electrode 13 and a positive voltage (for example, +0.8V) is applied to semiconductor substrate 11. At this time, a voltage is applied between semiconductor substrate 11 and second diffusion layer region 18 in the forward direction so that electrons are injected into semiconductor substrate 11. The injected electrons diffuse up to the PN junction between semiconductor substrate 11 and first diffusion layer region 17 and are therein accelerated by a strong electrical field so as to become hot electrons. These hot electrons generate electron-positive hole pairs in the PN junction. That is to say, a voltage in the forward direction is applied between semiconductor substrate 11 and second diffusion layer region 18 and, thereby, the electrons injected into semiconductor substrate 11 trigger generation of hot positive holes in the PN junction located on the opposite side. The hot positive holes generated in the PN junction are attracted in the direction toward gate electrode 13, having a negative potential, and, as a result, positive hole injection is carried out to first charge holding portion 61.

According to this second method, the electrons injected from second diffusion layer region 18 can generate hot positive holes in the PN junction between semiconductor substrate 11 and first diffusion layer region 17 that are triggered by the generation of electron-positive hole pairs in the PN junction, even in the case of the application of a low voltage insufficient for generation of hot positive holes due to tunneling between bands. Accordingly, the voltage at the time of the erasure operation can be lowered. In particular, in the case wherein offset regions 42 exist, the gate electrode to which the negative potential is applied does not influence the PN junction enough to create a sufficiently steep gradient. Therefore, hot positive holes due to tunneling between bands are not easily generated. The second method overcomes this defect so that the erasure operation can be implemented at a low voltage.

Here, in the case wherein data stored in first charge holding portion 61 is erased, +6V must be applied to first diffusion layer region 17 according to the first erasure method while +5V is sufficient according to the second erasure method. The voltage at the time of erasure can be reduced according to the second method, as described above, so that power consumption is reduced and deterioration of the semiconductor storage device due to hot carriers can be restricted.

This second method can be applied to the semiconductor storage device according to the present invention and, in addition, can be applied to the memory element (FIG. 21) of Saifun Semiconductors Ltd. according to a prior art. In this case, the operational voltage for memory erasure can be lowered so that the power consumption can be lowered and deterioration of the memory elements can be restricted.

According to the operational methods it becomes possible to selectively write in and erase two bits per transistor.

In addition, though according to the operational methods two bits are written in and erased per transistor by switching the source electrode and drain electrode, the device can be operated as a one bit memory by fixing the source electrode and the drain electrode. In this case, it becomes possible to connect one of the source/drain regions to the common fixed voltage and, thereby, the number of bit lines connected to the source/drain regions can be reduced by half.

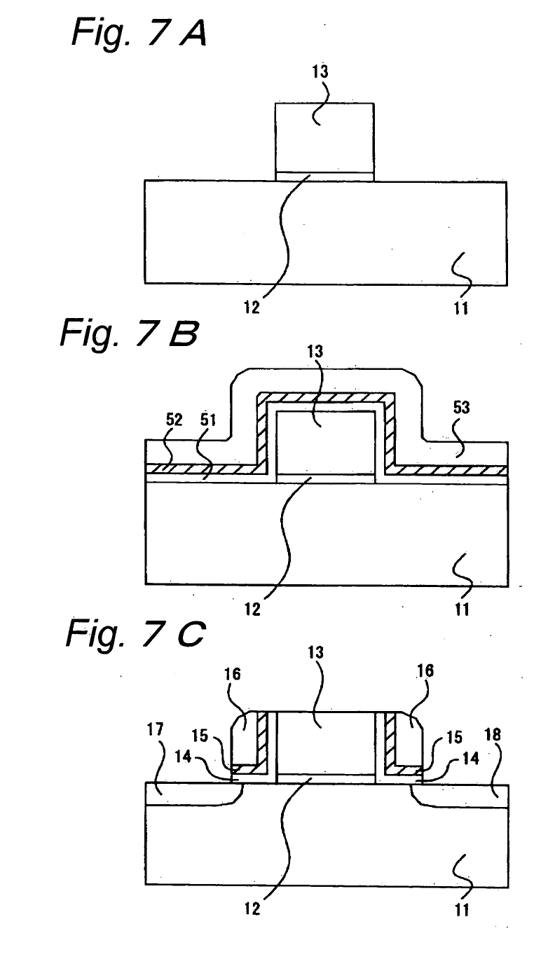

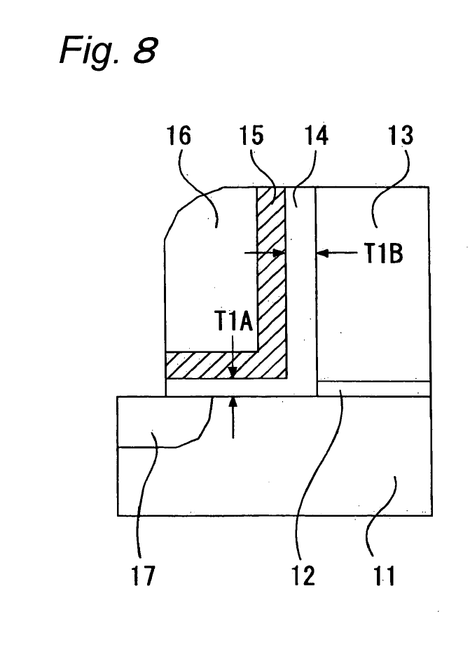

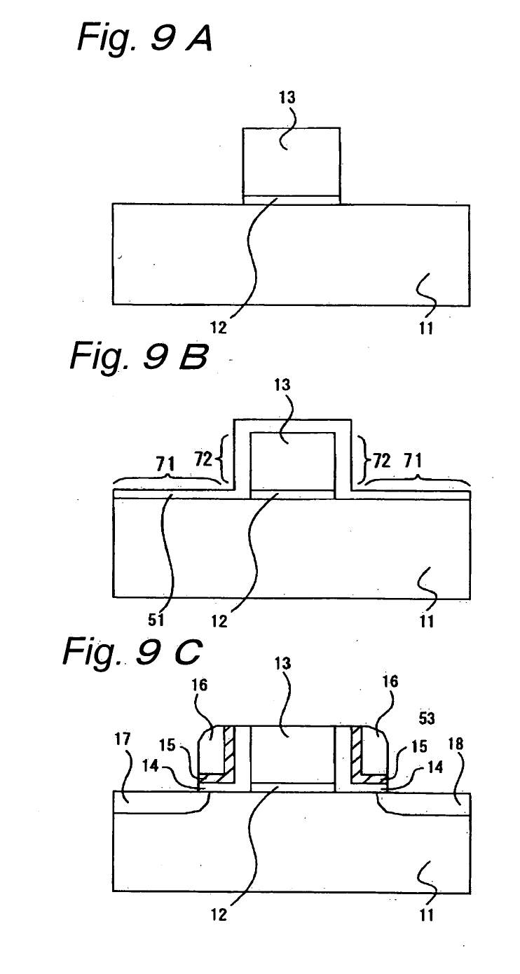

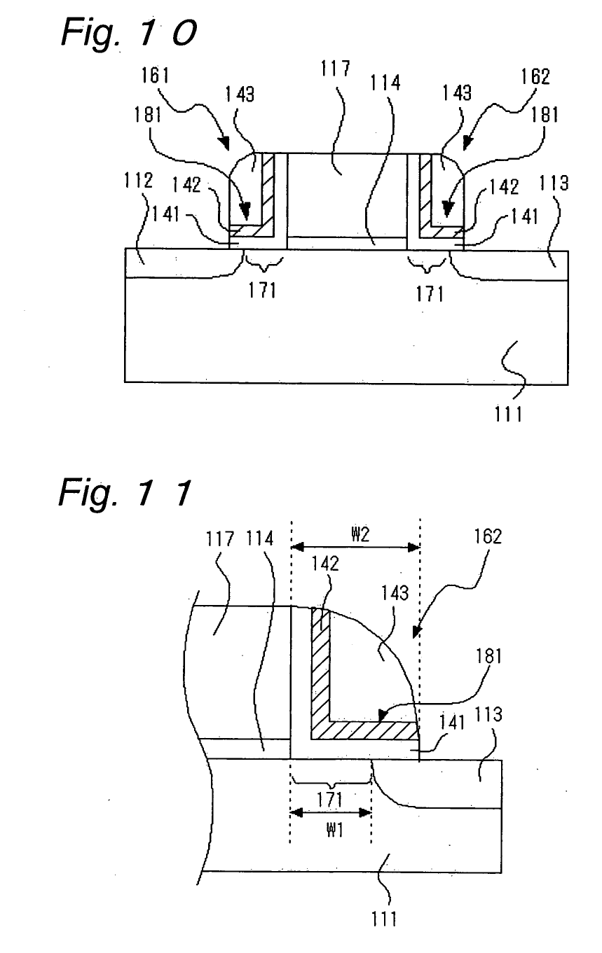

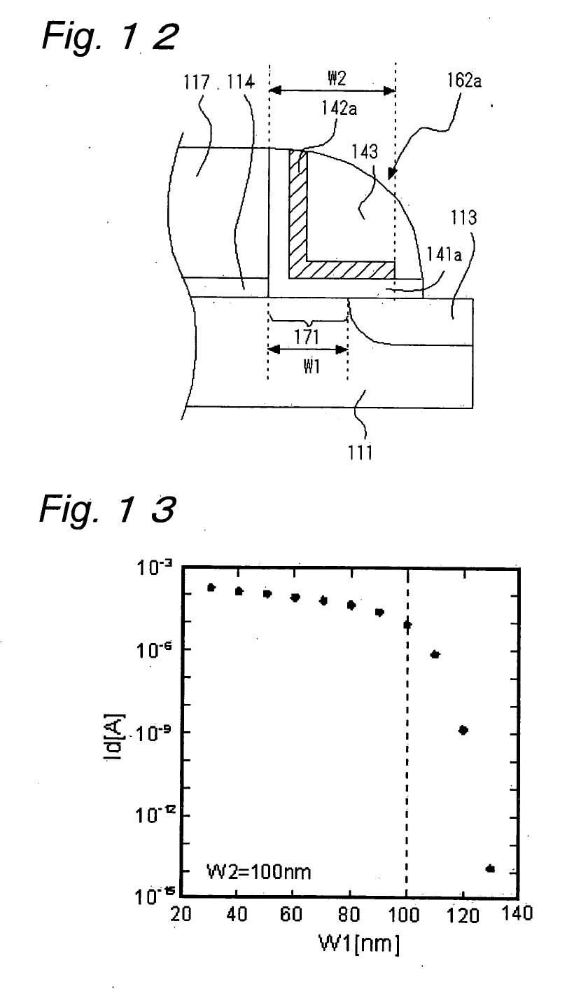

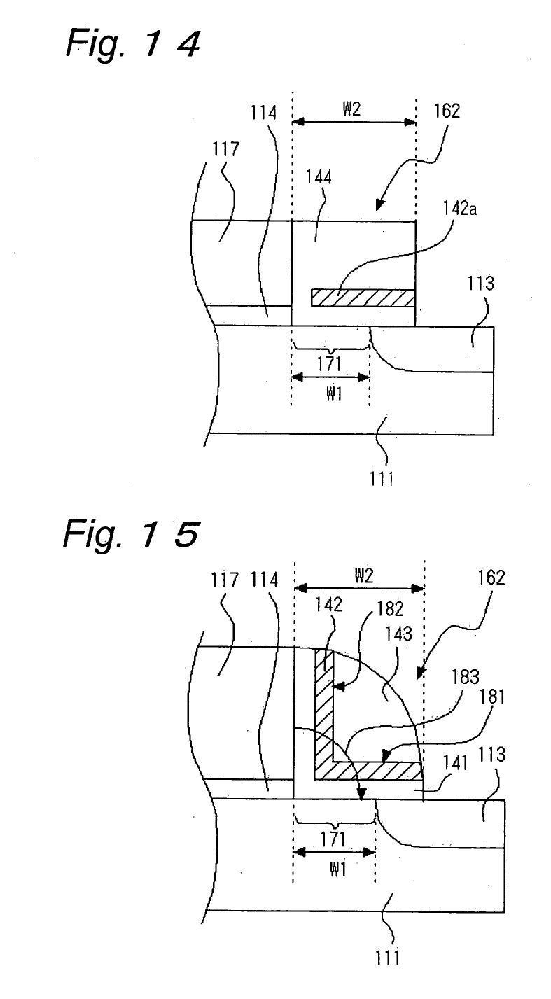

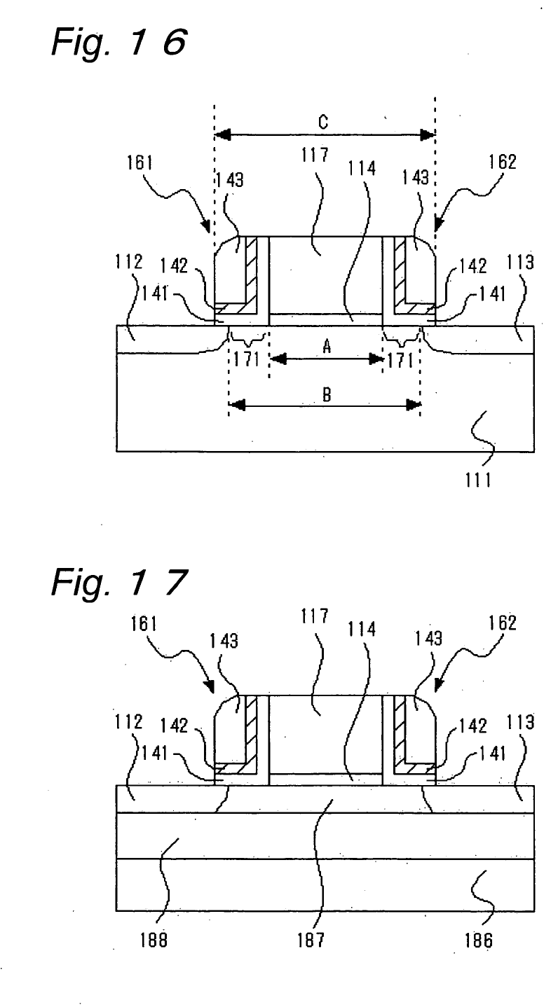

This memory element can be manufactured by means of approximately the same process as that for a conventional logic transistor. First, as shown in FIG. 7A, a gate insulating film 12 made of a silicon oxide nitride film having a film thickness of from approximately 1 nm to 6 nm and a gate electrode film made of polysilicon, a layered film of polysilicon and high melt point metal silicide or a layered film of polysilicon and metal having a film thickness of from approximately 50 nm to 400 nm are formed on semiconductor substrate 11, and patterning to a desired form is carried out so as to form a gate electrode 13. Here, as for the gate insulating film and the material for the gate electrode, materials used in the process for manufacturing logic transistors may be selected according to the scaling rules at the time of manufacture as described above and are not limited to the materials.

Next, as shown in FIG. 7B, a silicon oxide film 51 having a film thickness of from 1.5 nm to 15 nm, more preferably from 5 nm to 12 nm, is deposited over the entire surface of the obtained semiconductor substrate 11 according to a CVD (chemical vapor deposition) method. Here, silicon oxide film 51 may be formed by means of thermal oxidation. Then, a silicon nitride film 52 having a film thickness of from 2 nm to 15 nm, more preferably from 3 nm to 7 nm, is deposited over the entire surface of silicon oxide film 51 according to a CVD method. Furthermore, a silicon oxide film 53 having a film thickness of from 20 nm to 70 nm is deposited over the entire surface of silicon nitride film 52 according to a CVD method.

Next, as shown in FIG. 7C silicon oxide films 53, 51 and silicon nitride film 52 are etched back by means of anisotropic etching and, thereby, charge holding portions appropriate for data storage are formed in the form of sidewall spacers on the sidewalls of the gate electrode. After that, ions are injected using gate electrode 13 and charge holding portions in the form of sidewall spacers as a mask and, thereby, source/drain regions 17 and 18 are formed.

According to semiconductor storage device of the present Embodiment 1, charge holding portions of the memory transistor are formed so as to be independent of the gate insulating film and are formed on opposite sides of the gate electrode. Therefore, two bit operation is possible. Furthermore, the charge holding portions are separated from each other by the gate electrode and, therefore, interference at the time of rewriting can be effectively suppressed. In addition, the memory function carried out by charge holding portions and the transistor operation function carried out by the gate insulating film are independent of each other and, therefore, the short channel effects can be suppressed by reducing the thickness of the gate insulating film. Accordingly, miniaturization of elements becomes easy.

In addition, in order to form the element, the type of material for film suitable for the memory function of the charge holding portions can be selected independent of the type of film of the gate insulating film. In the present embodiment, charge holding portions formed of a layered film of silicon oxide films and a silicon nitride film (silicon oxide film/silicon nitride film/silicon oxide film) are used so as to increase the injection efficiency of charges and so as to reduce leakage of charge. Accordingly, a semiconductor storage device having operational characteristics of high-speed rewrite and excellent storage characteristics is provided.

### Embodiment 2

A memory element, which is a semiconductor storage device of the present Embodiment 2, is provided by restricting charge injection into charge holding portions from the gate electrode in the semiconductor storage device according to the above Embodiment 1.

The memory element of the present embodiment is described in reference to FIG. 8 below. The memory element of the present embodiment is characterized in that thickness T1B of silicon oxide film 14 on a sidewall of gate electrode 13 is greater than thickness T1A of silicon oxide film 14 on semiconductor substrate 11. Therefore, charge injection from gate electrode 13 to silicon nitride film 15 (or charge release from silicon nitride film 15 to gate electrode 13) can be effectively restricted. Accordingly, the rewriting characteristics of the memory element become stable and the reliability is increased.

The procedure for the formation of the memory element of the present Embodiment 2 is described in reference to FIGS. 9A, 9B and 9C. In the following, a case is described wherein the semiconductor substrate is a silicon substrate and the gate electrode is made of polycrystal silicon. As shown in FIG. 9A, a gate insulating film 12 and a gate electrode are formed on semiconductor (silicon) substrate 11. Here, it is preferable for gate electrode 13 to be made of polycrystal silicon. Next, as shown in FIG. 9B, silicon oxide film 51 is formed on the surface of silicon substrate 11 and gate electrode 13 by means of thermal oxidation. Here, the film thickness of silicon oxide film 51 on silicon substrate 11 (regions 71) is greater than the film thickness of silicon oxide film 51 on the sidewalls of gate electrode 13 (regions 72). This is because the thermal oxidation rate of polycrystal silicon is greater than that of single crystal silicon. After that, as shown in FIG. 9C, the memory element is completed according to the same procedure as in Embodiment 1.

According to the procedure, the difference in oxidation rates due to the difference in crystallinity is specifically utilized to selectively increase the thickness of the oxide film on the gate electrode sidewalls without increasing the number of steps. Accordingly, stable rewrite characteristics are obtained and it becomes possible to manufacture a memory element of a high reliability by means of a simple process.

### Embodiment 3

In the semiconductor storage device of the present Embodiment 3, charge holding portions 161 and 162 are formed of regions for charge storage (may be regions for storing charges or films having a function of charge storage) and of regions for preventing charges from escaping (may be films having a function of preventing charges from escaping), as shown in FIG. 10. The semiconductor storage device has, for example, ONO structure. That is to say, silicon nitride film 142, as an example of a film made of a first insulator, is sandwiched between silicon oxide film 141, as an example of a film made of a second insulator, and silicon oxide film 143, as an example of a film made of a third insulator so as to form charge holding portions 161 and 162. Here, silicon nitride film 142 has a function of charge storage. In addition, silicon oxide films 141 and 143 act as films having the function of preventing the escape of charges stored in the silicon nitride film 142.

In addition, regions for charge storage (silicon nitride films 142) in charge holding portions 161 and 162, respectively, overlap diffusion layer regions 112 and 113. Here, overlap means that, at least, portions of regions for charge storage (silicon nitride films 142) exist above the regions of, at least, portions of diffusion layer regions 112 and 113. Here, a semiconductor substrate is denoted as 111, a gate insulating film is denoted as 114, a single gate electrode formed on gate insulating film 114 is denoted as 117 and offset regions (between the gate electrode and the diffusion layer regions) are denoted as 171. The surface portion of semiconductor substrate 111 beneath gate insulating film 114 becomes a channel region, not shown.

The effects resulting from overlap of diffusion layer regions 112 and 113 by the regions (silicon nitride films 142) for charge storage in charge holding portions 161 and 162 are described below.

FIG. 11 is an enlarged view of a portion surrounding charge holding portion 162 on the right side of FIG. 10. The amount of offset between gate electrode 117 and diffusion layer region 113 is denoted as W1. In addition, the width of charge holding portion 162 shown in the cross section along the channel length direction of gate electrode 117 is denoted as W2 and, since the edge of silicon nitride film 142 in charge holding portion 162 on the side located away from gate electrode 117 agrees with the edge of charge holding portion 162 on the side away from gate electrode 117, the width of charge holding portion 162 is defined as W2. The amount of overlap between charge holding portion 162 and diffusion layer region 113 is represented as W2−W1. It is particularly important for silicon nitride film 142 in charge holding portion 162 to overlap diffusion layer region 113, that is to say, for the relationship of W2>W1 to be satisfied.

Here, as shown in FIG. 12, in the case wherein the edge of charge storage film 142a in charge holding portion 162a on the side located away from gate electrode 117 does not agree with the edge of charge holding portion 162a on the side located away from gate electrode 117, the distance between the edge of gate electrode 117 on the silicon oxide film 141a side and the edge of charge storage film 142a on the side located away from gate electrode 117 is defined as W2.

FIG. 13 shows drain current Id when the amount W1 of offset is changed while width W2 of charge holding portion 162 is fixed at 100 nm. Here, the drain current is calculated according to a device simulation wherein charge holding portion 162 is in the erased state (positive holes are stored) and diffusion layer regions 112 and 113, respectively, are used as the source electrode and the drain electrode.

As is clear from FIG. 13, the drain current rapidly decreases to a range wherein W1 is 100 nm, or greater, (that is to say, silicon nitride film 142 and diffusion layer region 113 do not overlap). The value of the drain current is approximately proportional to the rate of the read-out operation and, therefore, the memory performance undergoes a sudden deterioration when W1 is 100 nm, or greater. On the other hand, the drain current decreases gradually in a range wherein silicon nitride film 142 and diffusion layer region 113 overlap. Accordingly, it is preferable for, at least, a portion of silicon nitride film 142, which is a film having a function of charge storage, to overlap the source/drain region (diffusion layer region 113). It is also preferable in charge holding portion 161 for, at least, a portion of silicon nitride film 142, which is a film having a function of charge storage, to overlap the source/drain region (diffusion layer region 112) in the same manner as above.

Taking the result of the device simulation into consideration, memory cell arrays are fabricated wherein W2 is fixed at 100 nm and W1 is set at 60 nm and 100 nm as design values. In the case that W1 is 60 nm, silicon nitride film 142 and diffusion layer regions 112 and 113 overlap by 40 nm according to the design value while in the case that W1 is 100 nm, they do not overlap according to the design value. The case wherein W1 is set at 60 nm as the design value is 100 times as fast as the other case according to the access time for read-out as a result of measurement, wherein samples of the worst case are compared taking dispersion into consideration, of the period of time of read-out in these memory cell arrays. In practice it is preferable for the access read-out time to be 100 nanoseconds, or less, per bit but it was found that this condition cannot be achieved in the case of W1=W2. In addition, it was discovered that W2−W1>10 nm is preferable in the case wherein manufacturing dispersion is taken into consideration.

It is preferable to form a pinch off point on the side close to the drain region in the channel region by using diffusion layer region 112 as a source electrode and by using diffusion layer region 113 as a drain region in the same manner as in Embodiment 1 in order to read out data stored in charge holding portion 161 (region 181). That is to say, it is preferable to form a pinch off point in a region close to one of the two charge holding portions within the channel region at the time of read-out of data stored in the other charge holding portion. Thereby, data stored in charge holding portion 161 can be detected with a high precision regardless of the storage condition of charge holding portion 162, and this is a major factor that makes two bit operation possible.

On the other hand, in the case wherein data is stored in only one of the two charge holding portions or wherein the memory cells are utilized so that the two charge holding portions are in the same storage condition, a pinch off point is not necessarily formed at the time of read-out.

Here, it is preferable to form a well region (P type well in the case of an N channel element) in the surface of semiconductor substrate 111, though this is not shown in FIG. 10. It becomes easy to adjust the impurity concentration in the channel region to the value appropriate for the memory operations (rewrite operation and read-out operation) and, in addition, it becomes easy to control other electrical properties (resistance to voltage, junction capacitance, short channel effects) by forming a well region.

It is preferable for charge holding portions 161 and 162 to include charge storage films having a function of charge storage and insulating films from the viewpoint of increasing the storage characteristics of the memory. In this embodiment, silicon nitride films 142 having levels that trap charges are used as the charge storage films and silicon oxide films 141 and 143 that prevent dispersion of the charges stored in the charge storage films are used as the insulating films. The charge holding portions include charge storage films and insulating films so as to prevent discharge of charges and, thereby, the storage characteristics can be improved. Furthermore, the volume of the charge storage films can be reduced to some extent in comparison with the case wherein charge holding portions are formed solely of charge storage films. Shift of charges within the charge storage films can be restricted by reducing the volume of the charge storage films and, thereby, change in characteristics due to charge shift while data is being stored can be prevented from occurring.

In addition, it is preferable for charge holding portions 161 and 162 to included charge storage films, which are placed approximately parallel to the surface of gate insulating film 114, in other words, it is preferable for the upper surfaces of charge storage films in charge holding portions 161 and 162 to be placed at positions an equal distance away from the top surface of gate insulating film 114. Concretely, as shown in FIG. 14, charge storage film 142a of charge holding portion 162 has a surface approximately parallel to the surface of gate insulating film 114. In other words, it is preferable for charge storage film 142a to be formed to have a uniform height relative to the level of the surface of gate insulating film 114. Charge storage film 142a, which is parallel to the surface of gate insulating film 114, is located in charge holding portion 162 and, thereby, ease of formation of the inversion layer in offset region 171 according to the quantity of stored charge in charge storage film 142a can be effectively controlled and, thereby, the memory effects can be increased. In addition, charge storage film 142a is approximately parallel to the surface gate insulating film 114 and, thereby, change in the memory effects can be restricted to a comparatively small amount even in the case wherein the amount (W1) of offset varies. Furthermore, a shift of the charge in the direction toward the upper portion of charge storage film 142a can be suppressed and change in characteristics due to charge shift while data is being stored can be prevented from occurring.

Moreover, it is preferable for charge holding portion 162 to include an insulating film (for example, a portion of silicon oxide film 144 above offset region 171) that separates charge storage film 142a, which is approximately parallel to the surface of gate insulating film 114, from the channel region (or well region). This insulating film restricts discharge of the charge stored in the charge storage film so that a semiconductor storage device having improved storage characteristics can be obtained.

Here, the film thickness of charge storage film 142a is adjusted and the film thickness of the insulating film (portion of silicon oxide film 144 above offset region 171) beneath charge storage film 142a is adjusted to be constant and, thereby, it becomes possible to maintain an approximately constant distance between the surface of semiconductor substrate 111 and the charge stored in the charge storage film. That is to say, the distance between the surface of the semiconductor substrate and the charge stored in the charge storage film can be adjusted to be in the range between the minimum film thickness value of the insulating film beneath charge storage film 142a and the sum of the maximum film thickness value of the insulating film beneath charge storage film 142a and the maximum film thickness value of charge storage film 142a. Thereby, it becomes possible to generally control the density of the lines of electric force generated by the charge stored in charge storage film 142a and, thus, it becomes possible to make the dispersion in the magnitude of the memory effects of the memory elements very small.

### Embodiment 4

In the present Embodiment 4, charge storage film 142 in charge holding portion 162 has a form of a combination of films having approximately uniform thicknesses positioned approximately parallel to the surface of gate insulating film 114 (arrow 181) and positioned approximately parallel to the sides of gate electrode 117 (arrow 182).

In the case that a positive voltage is applied to gate electrode 117, the lines of electric force in charge holding portion 162 pass through silicon nitride film 142 twice (portions indicated by arrow 182 and arrow 181) as shown by arrow 183. Here, in the case wherein a negative voltage is applied to gate electrode 117, the direction of the lines of electric force is reversed. Here, dielectric constant of silicon nitride film 142 is approximately 6 while the dielectric constant of silicon oxide films 141 and 143 is approximately 4. Accordingly, in the case wherein the charge storage film indicated by arrows 181 and 182 exists, the effective dielectric constant of charge holding portion 162 in the direction of lines of electric force 183 is greater than in the case wherein the charge storage film indicated solely by arrow 181 exists and the voltage gap between both ends of the lines of electric force can be reduced. That is to say, the major portion of the voltage applied to gate electrode 117 is used in order to enhance the magnetic field in offset region 171.

A charge is injected into silicon nitride film 142 at the time of the rewrite operation because the generated charge is attracted by an electrical field in offset region 171. Accordingly, the charge injected to charge holding portion 162 at the time of the rewrite operation increases by providing the charge storage film indicated by arrow 182 so that the rate of rewriting increases.

Here, in the case wherein the silicon oxide film 143 portion is made of a silicon nitride film, that is to say, in the case wherein the charge storage film is not positioned at a uniform height relative to the level of the surface of gate insulating film 114, shift of charge in the upward direction in the silicon nitride film becomes significant and the storage characteristics deteriorate.

It is more preferable for the charge storage film to be formed of a high dielectric material, such as hafnium oxide, having a relatively great dielectric constant instead of the silicon nitride film.

Furthermore, it is preferable for charge holding portions 161 and 162 to further include an insulating film (portion of silicon oxide film 141 above offset region 171) that separates the charge storage films approximately parallel to the surface of gate insulating film 114 from the channel region (or well region). This insulating film restricts discharge of the charge stored in the charge storage film so that the storage characteristics can be improved.

In addition, it is preferable for the charge holding portions to further include an insulating film (portion of silicon oxide film 141 contacting gate electrode 117) that separates the gate electrode from the charge storage films extending in the direction approximately parallel to the sides of the gate electrode. This insulating film prevents change in the electrical characteristics due to the injection of the charge from the gate electrode to the charge storage films and the reliability of the semiconductor storage device can be improved.

Furthermore, it is preferable in the same manner as in Embodiment 3 for the film thickness of the insulating film (portion of silicon oxide film 141 above offset region 171) beneath charge storage film 142 to be adjusted to be constant and, in addition, for the film thickness of the insulating film (portion of silicon oxide film 141 contacting gate electrode 117) placed on the a side of the gate electrode to be adjusted to be constant. Thereby, it becomes possible to generally control the density of the lines of electric force generated by the charge stored in charge storage film 142 and charge leakage can be prevented.

### Embodiment 5

The present Embodiment 5 relates to the optimization of the distances between the gate electrode and the charge holding portions and the source/drain regions.

As shown in FIG. 16, the length of the gate electrode in the cross section along the channel length direction is denoted as A, the distance (channel length) between the source/drain regions is denoted as B and the distance between the edge of one of the charge holding portions and the edge of the other charge holding portion, that is to say, the distance between the edge (on the side separated from the gate electrode) of the film having the function of charge storage within one of the charge holding portions and the edge (on the side separated from the gate electrode) of the film having the function of charge storage within the other charge holding portion in the cross sectional view along the channel length direction, is denoted as C.

First, B<C is preferable. Offset regions 171 exist between the portion beneath gate electrode 117 and source/drain regions 112 and 113 within the channel region. In the case of B<C, the charges stored in charge holding portions 161 and 162 (silicon nitride film 142) leads to an effective change in the ease of inversion throughout the entire regions of offset regions 171. Accordingly, the memory effect increases and, in particular, increase in the rate of the read-out operation is implemented.

In addition, in the case that gate electrode 117 and source/drain regions 112 and 113 offset each other, that is to say, in the case of A<B, ease of inversion in the offset regions at the time when a voltage is applied to the gate electrode greatly changes according to the amounts of charges stored in the charge holding portions so that the memory effects increase and the short channel effects can be reduced. Here, it is not necessary for the offset regions to exist as long as the memory effects appear. Even in the case wherein there are no offset regions 171, the memory effects appear in charge holding portions 161 and 162 (silicon nitride film 142) when the impurity concentrations in source/drain regions 112 and 113 are sufficiently low.

Accordingly, A<B<C is most preferable.

### Embodiment 6

The semiconductor storage device of this embodiment has essentially the same configuration as in Embodiment 3 except that the semiconductor substrate is an SOI substrate, as shown in FIG. 17.

In this semiconductor storage device a buried oxide film 188 is formed on semiconductor substrate 186 and an SOI layer is formed on top of the buried oxide film. Diffusion layer regions 112 and 113 are formed within the SOI layer and the remaining portion of the region is used as a body region 187.

This semiconductor storage device has the same working effects as the semiconductor storage device of Embodiment 3. Furthermore, the junction capacitances between diffusion layer regions 112 and 113 and body region (semiconductor layer) 187 can be made very low and, therefore, increase in the operational speed of the elements and the lowering of power consumption are made possible.

### Embodiment 7

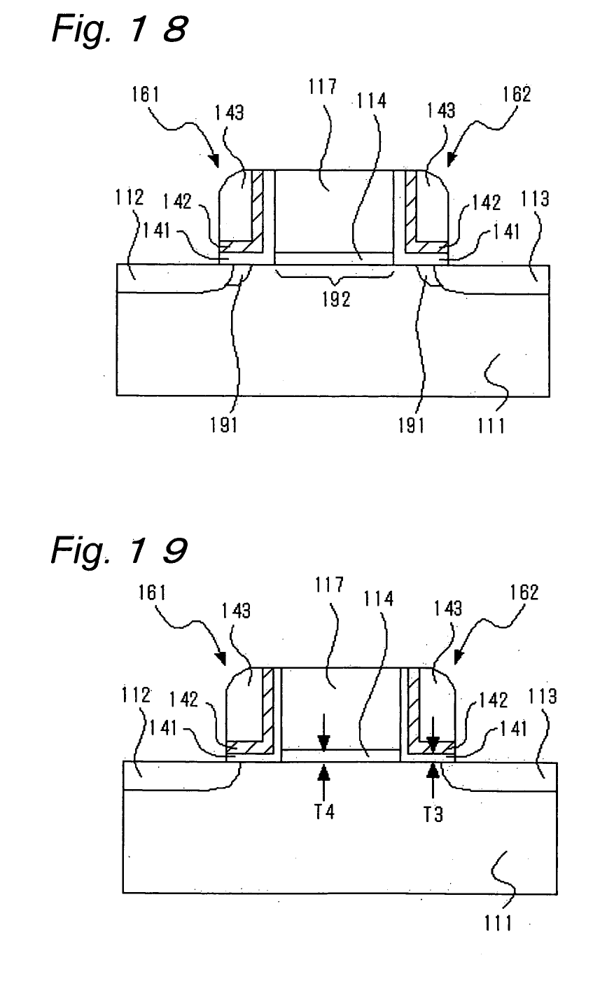

The semiconductor storage device of this embodiment has essentially the same configuration as in Embodiment 3 except that P type high concentration regions 191 are added to adjoin N type source/drain regions 112 and 113 on the channel side as shown in FIG. 18.

That is to say, the concentration of the impurity (for example, boron) that provides the P type in P type high concentration regions 191 is higher than the concentration of the impurity that provides the P type in region 192. It is appropriate for the P type impurity concentration in P type high concentration regions 191 to be, for example, approximately 5×10¹⁷ cm⁻³ to 1×10¹⁹ cm^{-1 3}. In addition, the P type impurity concentration of region 192 is, for example, 5×10¹⁶ cm⁻³ to 1×10¹⁸ cm⁻³.

As described above, P type high concentration regions 191 are provided and, thereby, the junctions between diffusion layer regions 112 and 113 and semiconductor substrate 111 have steep gradients directly beneath charge holding portions 161 and 162. Therefore, hot carriers do not easily occur at the time of the write-in and erasure operations and, therefore, it becomes possible to lower the voltages for the write-in operation and for the erasure operation or it becomes possible to increase the rates of the write-in operation and of the erasure operation. Furthermore, since the impurity concentration of region 192 is relatively low, the threshold value when the memory is in the erased condition is low and the drain current becomes large. Therefore, the rate of read-out increases. Accordingly, a semiconductor storage device having a low rewrite voltage or having a high rewrite speed and having a high read-out speed can be obtained.

In addition, P type high concentration regions 191 are provided in the vicinity of the source/drain regions and beneath the charge holding portions 161, 162 (that is to say, not directly beneath the gate electrode 117) in FIG. 18 and, thereby, the threshold value of the entire transistor significantly increases. The degree of this increase is significantly large in comparison with the case wherein P type high concentration regions 191 are located directly beneath the gate electrode 117. In the case wherein the charges (electrons in the case that the transistor is of the N channel type) are stored for write-in in the charge holding portions 161, 162, this gap becomes even greater. On the other hand, in the case wherein sufficient charges (positive holes in the case that the transistor is of the N channel type) are stored for erasure in the charge holding portions 161, 162, the threshold value of the entire transistor drops to the threshold value determined by the impurity concentration of the channel region (region 192) beneath the gate electrode 117. That is to say, the threshold value at the time of erasure does not depend on the impurity concentration of P type high concentration regions 191 while the threshold value at the time of write-in is very greatly affected by the impurity concentration of P type high concentration regions 191. Accordingly, P type high concentration regions 191 are positioned in the vicinity of the source/drain regions beneath the charge holding portions and, thereby, the threshold value alone at the time of write-in can be altered to a great extent so that the memory effects (difference in threshold value between the time of write-in and the time of erasure) can be significantly increased.

### Embodiment 8

The semiconductor storage device of the present embodiment has essentially the same configuration as in Embodiment 3 except that the thickness (T3) of the insulating films for separating the charge storage films (silicon nitride film 142) from the channel region or from the well region is less than the thickness (T4) of gate insulating film 114, as shown in FIG. 19.

Thickness T4 of gate insulating film 114 has the lower limit value because resistance to voltage is required for the gate insulating film at the time of the rewrite operation of memory. However, it is possible to make thickness T3 of the insulating film to be less than T4, regardless of the requirement of resistance to voltage. Injection of charges to charge holding portions 161, 162 is made easy by reducing T3 and it becomes possible to lower the voltage for the write-in operation and for the erasure operation or it becomes possible to increase the rate of the write-in operation and of the erasure operation and, in addition, the amounts of the charges induced in the channel region or in the well region at the time the charges have been stored in silicon nitride film 142 increase and, therefore, the memory effects can be increased.

Accordingly, when T3<T4 is satisfied, it becomes possible to lower the voltage for the write-in operation and for the erasure operation or it becomes possible to increase the rate of the write-in operation without lowering the resistance of the memory to voltage and, furthermore, it becomes possible to increase the memory effects.

Here, it is preferable for thickness T3 of the insulating film to be 0.8 nm, or greater, which is the limit wherein the uniformity and quality of the film are maintained at a constant level according the manufacturing process and wherein the storage characteristics do not undergo extreme deterioration.

### Embodiment 9

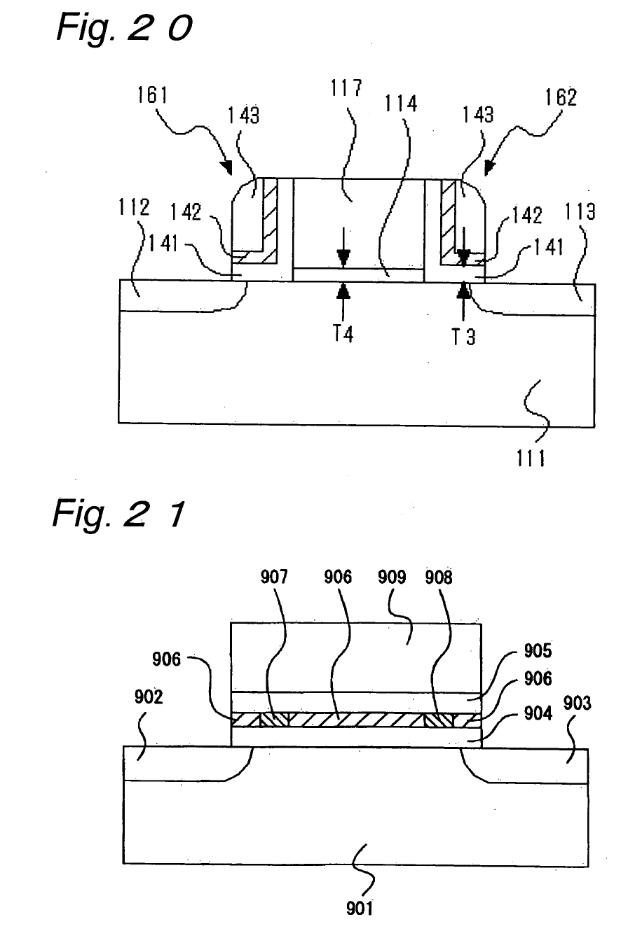

The semiconductor storage device of this embodiment has essentially the same structure as in Embodiment 3 except that the thickness (T3) of the insulating films (silicon oxide film 141) for separating the charge storage films (silicon nitride film 142) from the channel region or from the well region is greater than the thickness (T4) of gate insulating film 114, as shown in FIG. 20.

Thickness T4 of gate insulating film 114 has the upper limit value due to the requirement for prevention of short channel effects of the element. However, it is possible to make thickness T3 of the insulating film greater than T4, regardless of the requirement for prevention of short channel effects. By increasing T3, it becomes possible to prevent the charges stored in the charge holding portions from discharging and to improve the storage characteristics of the memory.

Accordingly, when T3>T4 is satisfied, it becomes possible to improve the storage characteristics without negatively affecting the short channel effects of memory.

Here, it is preferable for thickness T3 of the insulating film to be 20 nm, or less, taking reduction in the rate of the rewrite operation into consideration.

1. A semiconductor storage device comprising:
a semiconductor substrate;
a gate insulating film formed on the semiconductor substrate;
a single gate electrode formed on the gate insulating film;
two charge holding portions formed on the sidewalls on opposite sides of the single gate electrode;
two diffusion layer regions corresponding to the two charge holding portions respectively; and,
a channel region placed beneath the single gate electrode, wherein
the charge holding portions have a structure such that a film made of a first insulator having a function of holding charge is sandwiched between a second insulator and a third insulator, and
the charge holding portions are constituted such that the amount of current flowing between one of the diffusion layer regions and the other of the diffusion layer regions at the time of application of a voltage to the gate electrode is changed due to the quantity of charge held in the first insulator.

2. The semiconductor storage device according to claim 1, wherein expressions X1>X2 and X1>X3 are satisfied, where
the X1 represents an energy gap between the vacuum level and the lowest level of a conduction band of the first insulator,
the X2 represents an energy gap between the vacuum level and the lowest level of a conduction band of the second insulator, and
the X3 represents an energy gap between the vacuum level and the lowest level of a conduction band of the third insulator.

3. The semiconductor storage device according to claim 1, wherein expressions Φ1<Φ2 and Φ1<Φ3 are satisfied, where
the Φ1 represents an energy gap between the vacuum level and the highest level of a valence band of the first insulator,
the Φ2 represents an energy gap between the vacuum level and the highest level of a valence band of the second insulator, and
the Φ3 represents an energy gap between the vacuum level and the highest level of a valence band of the third insulator.

4. The semiconductor storage device according to claim 1, wherein all expressions of: X1>X2, X1>X3, Φ1<Φ2 and Φ1<Φ3 are satisfied, where
the X1 represents an energy gap between the vacuum level and the lowest level of the conduction band of the first insulator,
the X2 represents an energy gap between the vacuum level and the lowest level of the conduction band of the second insulator,
the X3 represents an energy gap between the vacuum level and the lowest level of the conduction band of the third insulator,
the Φ1 represents an energy gap between the vacuum level and the highest level of the valence band of the first insulator,
the Φ2 represents an energy gap between the vacuum level and the highest level of the valence band of the second insulator, and
the Φ3 represents an energy gap between the vacuum level and the highest level of the valence band of the third insulator.

5. The semiconductor storage device according to claim 1, wherein
the first insulator is of silicon nitride, and
the second and third insulators are of silicon oxide.

6. The semiconductor storage device according to claim 5, wherein
the second insulator that is of silicon oxide is in a film form and separates the semiconductor substrate from the first insulator, and
the film formed of the second insulator on the semiconductor substrate has a thickness of no less than 1.5 nm and of no greater than 15 nm.

7. The semiconductor storage device according to claim 5, wherein
the film formed of the first insulator, which is of silicon nitride, on the semiconductor substrate has a thickness of no less than 2 nm and of no greater than 15 nm.

8. The semiconductor storage device according to claim 1, wherein
the second insulator is in a film form and separates the semiconductor substrate and the sidewalls of the gate electrode from the first insulator, and
the thickness of the film made of the second insulator in the vicinity of the sidewalls of the gate electrode is greater than the thickness of the film made of the second insulator on the semiconductor substrate.

9. The semiconductor storage device according to claim 5, wherein
the thickness of the film made of the second insulator on the semiconductor substrate is less than the thickness of the gate insulating film and is not less than 0.8 nm.

10. The semiconductor storage device according to claim 5, wherein
the thickness of the film made of the second insulator on the semiconductor substrate is greater than the thickness of the gate insulating film and is not greater than 20 nm.

11. The semiconductor storage device according to claim 1, wherein
at least a portion of the film made of the first insulator having a function of charge storage overlaps a portion of the diffusion layer regions.

12. The semiconductor storage device according to claim 1, wherein
the film made of the first insulator having a function of charge storage includes a portion having a surface approximately parallel to the surface of the gate insulating film.

13. The semiconductor storage device according to claim 12, wherein
the film made of the first insulator having a function of charge storage includes a portion that extends approximately parallel to sides of the gate electrode.
